(19) United States
(12) Patent Application Publication
(10) Pub. No.: US 2019/0304756 A1
(43) Pub. Date: Oct. 3, 2019

(54) SEMICONDUCTOR CHAMBER COATINGS AND PROCESSES

(71) Applicant: Applied Materials, Inc., Santa Clara, CA (US)

(72) Inventors: Laksheswar Kalita, San Jose, CA (US); Soonam Park, Sunnyvale, CA (US); Toan Q. Tran, San Jose, CA (US); Lili Ji, San Jose, CA (US); Dmitry Lubomirsky, Cupertino, CA (US); Akhil Devarakonda, San Jose, CA (US); Tien Fak Tan, Campbell, CA (US); Tae Won Kim, San Jose, CA (US); Saravjeet Singh, Sunnyvale, CA (US); Alexander Tam, Union City, CA (US); Jingchun Zhang, Cupertino, CA (US); Jing J. Zhang, San Jose, CA (US)

(73) Assignee: Applied Materials, Inc., Santa Clara, CA (US)

(21) Appl. No.: 16/374,420

(22) Filed: Apr. 3, 2019

Related U.S. Application Data
(60) Provisional application No. 62/652,191, filed on Apr. 3, 2018.

(51) Int. Cl. H01J 37/32; C23C 4/134; C23C 4/11

(52) U.S. Cl. CPC H01J 37/32495; H01J 37/3244; H01L 21/67069; C23C 4/11; H01J 2237/3341; C23C 4/134

(57) ABSTRACT

Systems and methods may be used to produce coated components. Exemplary chamber components may include an aluminum, stainless steel, or nickel plate defining a plurality of apertures. The plate may include a hybrid coating, and the hybrid coating may include a first layer comprising a corrosion resistant coating. The first layer may extend conformally through each aperture of the plurality of apertures. The hybrid coating may also include a second layer comprising an erosion resistant coating extending across a plasma-facing surface of the semiconductor chamber component.

### CROSS-REFERENCE TO RELATED APPLICATIONS

This application claims the benefit of U.S. Provisional Application No. 62/652,191, filed Apr. 3, 2018, and which is hereby incorporated by reference in its entirety for all purposes.

### TECHNICAL FIELD

The present technology relates to semiconductor systems, processes, and equipment. More specifically, the present technology relates to systems including or forming coatings on chamber components.

### BACKGROUND

Integrated circuits are made possible by processes which produce intricately patterned material layers on substrate surfaces. Producing patterned material on a substrate requires controlled methods for removal of exposed material. Chemical etching is used for a variety of purposes including transferring a pattern in photoresist into underlying layers, thinning layers, or thinning lateral dimensions of features already present on the surface. Often it is desirable to have an etch process that etches one material faster than another facilitating, for example, a pattern transfer process. Such an etch process is said to be selective to the first material. As a result of the diversity of materials, circuits, and processes, etch processes have been developed with a selectivity towards a variety of materials.

Etch processes may be termed wet or dry based on the materials used in the process. A wet HF etch preferentially removes silicon oxide over other dielectrics and materials. However, wet processes may have difficulty penetrating some constrained trenches and also may sometimes deform the remaining material. Dry etches produced in local plasmas formed within the substrate processing region can penetrate more constrained trenches and exhibit less deformation of delicate remaining structures. However, local plasmas may damage the substrate through the production of electric arcs as they discharge. Local plasmas, as well as plasma effluents may damage chamber components as well.

Thus, there is a need for improved systems and methods that can be used to produce high quality devices and structures. These and other needs are addressed by the present technology.

### SUMMARY

Systems and methods may be used to produce coated components. Exemplary chamber components may include an aluminum, stainless steel, or nickel plate defining a plurality of apertures. The plate may include a hybrid coating, and the hybrid coating may include a first layer comprising a corrosion resistant coating. The first layer may extend conformally through each aperture of the plurality of apertures. The hybrid coating may also include a second layer comprising an erosion resistant coating extending across a plasma-facing surface of the semiconductor chamber component.

In some embodiments, the first layer may be an anodization, electroless nickel plating, electroplated nickel, aluminum oxide, or barium titanate. The first layer may be characterized by a thickness of less than or about 25 μm. The second layer may be or include yttrium oxide. The second layer may be characterized by a thickness of less than or about 25 μm. The second layer may further include aluminum or zirconium within the yttrium oxide. Surfaces of the plate may be textured to a depth of at least about 1 μm. The plurality of apertures may be characterized by a taper at least partially extending through each aperture and a straight section at least partially extending through each aperture. A diameter of the straight section may be less than or about twice a height of the straight section. Each aperture of the plurality of apertures may extend from a first surface of the plate to a second surface of the plate opposite the first surface. A diameter of each aperture at the first surface may be less than or about 10 mm. The hybrid coating may be configured to reduce wafer-level particle contribution from the semiconductor chamber component to less than or about 5 adders of size 35 nm.

The present technology may also encompass methods of coating a component of a semiconductor processing chamber. The methods may include positioning the component within a chamber. The component may define a plurality of apertures including a taper extending at least partially through a first section of each aperture of the plurality of apertures. The taper may be characterized by an angle of taper through the first section of each aperture of the plurality of apertures. The methods may include positioning a spray nozzle at a nozzle angle relative to the component. The nozzle angle may be defined as about 90 minus the angle of taper. The methods may also include coating the component.

In some embodiments, the coating may be or include a plasma-sprayed coating of yttrium oxide. The coating may further include particles of aluminum or zirconium within the yttrium oxide. The methods may also include laterally translating the component during the coating while the spray nozzle remains fixed. Each aperture of the plurality of apertures may further include a second section characterized by a cylindrical profile. The second section may be characterized by a diameter less than or equal to twice a height of the second section. The component may be characterized by a first surface and a second surface opposite the first surface. The first section of each aperture may extend from the first surface to the second section of each aperture. The second section of each aperture may extend from the first section of each aperture to a third section of each aperture. The third section of each aperture may flare from the second section of each aperture to the second surface of the component. An angle of flare may be equal to the angle of taper. Coating the component may coat greater than 95% of a surface area of the component defining each aperture.

The present technology may also encompass semiconductor processing chambers. The chambers may include a processing region configured to house a substrate. A bias plasma may be formable within the processing region. The chambers may include a remote plasma region within which a remote plasma is formable. The chambers may also include a plate positioned between the processing region and the remote plasma region. The plate may at least partially define the processing region. The plate may include a first surface facing towards the remote plasma region and a second surface facing towards the processing region. The second surface may be opposite the first surface. The plate may define a plurality of apertures, and the plate may include a hybrid coating including a first layer including a corrosion resistant coating. The first layer may extend conformally through each aperture of the plurality of apertures. The coating may also include a second layer including an erosion resistant coating extending across the second surface of the plate facing the processing region of the semiconductor processing chamber. In some embodiments, the chamber may also include a slit valve configured to provide access to the processing region. A chamber-facing surface of the slit valve may include the hybrid coating extending across the slit valve and between the slit valve and a seal coupled with the slit valve.

Such technology may provide numerous benefits over conventional systems and techniques. For example, coatings according to the present technology may provide both corrosion and erosion protection to chamber components that may limit component degradation. Additionally, the coatings may also protect substrates being processed from contamination due to degrading components. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to some embodiments of the present technology.

FIG. 2 shows a schematic cross-sectional view of an exemplary processing chamber according to some embodiments of the present technology.

FIG. 3 shows a schematic cross-sectional view of an exemplary processing chamber according to some embodiments of the present technology.

FIGS. 4A-4E illustrate schematic cross-sectional views of exemplary apertures that may be formed in a chamber component according to some embodiments of the present technology.

FIG. 5 illustrates a schematic cross-sectional view of a coating system for coating a chamber component according to some embodiments of the present technology.

FIG. 6 illustrates exemplary operations in methods according to some embodiments of the present technology.

FIGS. 7A-7B illustrate schematic cross-sectional views of exemplary aperture coatings that may be formed on a chamber component according to some embodiments of the present technology.

FIG. 8 shows a top plan view of an exemplary processing system according to some embodiments of the present technology.

FIG. 9 illustrates a schematic cross-sectional view of a processing chamber slit valve according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include partial or exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

The present technology includes systems and components for semiconductor processing of small pitch features. As line pitch is reduced, standard lithography processes may be limited, and alternative mechanisms may be used in patterning. Conventional technologies have struggled with these minimal patterning and removal operations, especially when exposed materials on a substrate may include many different features and materials, some to be etched and some to be maintained. Additionally, as feature sizes continue to shrink the amount of extraneous particles that may cause shorting or damage to a device may reduce as well.

Atomic layer etching is a process that utilizes a multiple-operation process of damaging or modifying a material surface followed by an etching or removal operation. The etching operation may be performed at chamber conditions allowing the modified material to be removed, but limiting interaction with unmodified materials. This process may then be cycled any number of times to etch additional materials. Some chambers available can perform both operations within a single chamber. The modification may be performed with a bombardment operation at the substrate level, followed by a remote plasma operation to enhance etchant precursors capable of removing only the modified materials.

During the modification operation, a wafer-level plasma may be formed within the processing region. For example, a bias plasma may be formed from the substrate support, which may form a plasma of a precursor within a processing region. The plasma may direct ions to the surface of the substrate to leverage higher ion density. The bias plasma may be a capacitively-coupled plasma, which may produce plasma effluents throughout the processing region with a high plasma potential. An inductively-coupled plasma formed above the substrate may provide a more controlled delivery of plasma effluents, while the capacitively-coupled plasma may develop plasma species that may cause bombardment of chamber components that may lead to sputtering, which may cause damage to chamber components as well as deposition of particulate matter on the substrate being processed.

During the removal or etching operation, an additional plasma process may be performed in which plasma effluents are produced in a remove portion of the chamber, or in a fluidly coupled external unit. These effluents may be delivered through the chamber to interact with the substrate to be processed. During these processes, chamber components may be contacted by one or both of the modifying plasma effluents or the removal plasma effluents. The modifying plasma effluents may cause physical damage to chamber components, which may be termed erosion. The etching plasma effluents may cause a chemical damage to chamber components, which may be termed corrosion.

Conventional technologies have struggled to limit both corrosion and erosion to chamber components, and tend to replace components regularly due to the damage caused by one or both of these mechanisms. However, additional issues include unwanted deposition of metal or other particulate matter from the chamber components or formed materials, which may impact device quality when these materials deposit on the substrate. The present technology overcomes these issues by utilizing one or more coatings to protect chamber components from one or both of corrosion and erosion. Additionally, the present technology provides improved coverage of chamber components with protective coatings, which improve lifetime and stability of the coatings.

Although the remaining disclosure will routinely identify specific etching processes utilizing the disclosed technology, it will be readily understood that the systems and methods are equally applicable to deposition and cleaning processes as may occur in the described chambers and also include plasma or other reactive materials. Accordingly, the technology should not be considered to be so limited as for use with etching processes alone.

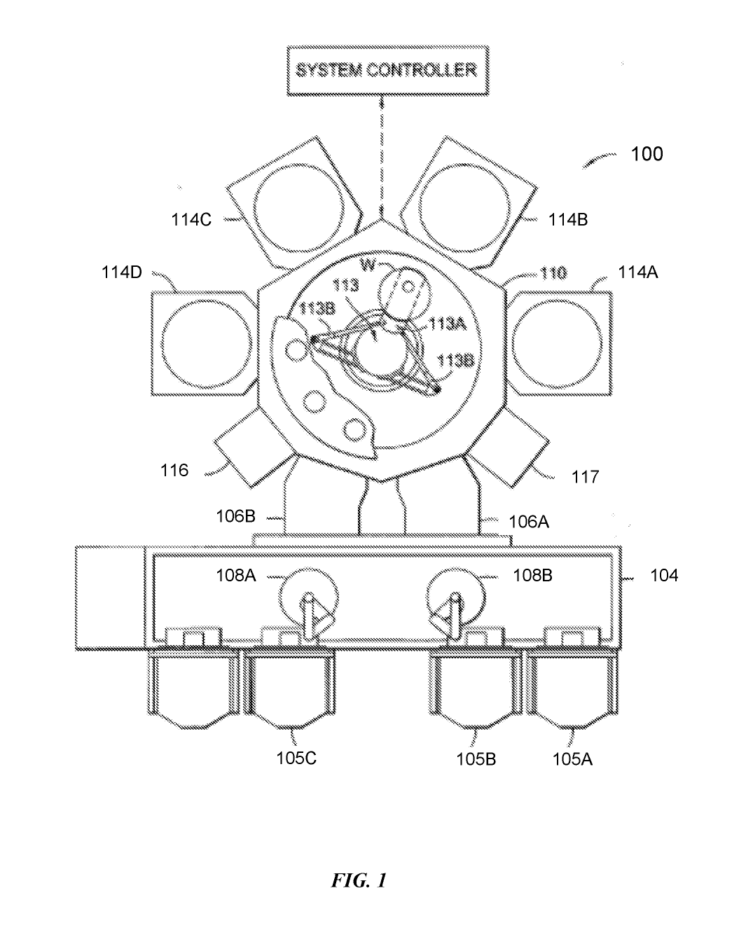

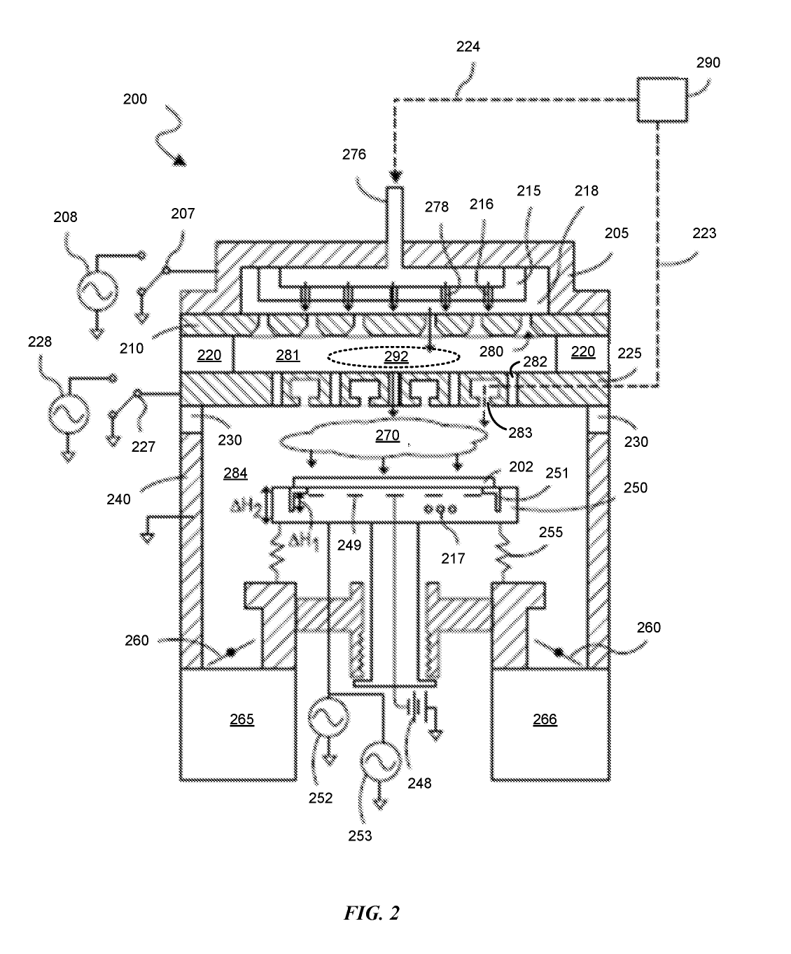

FIG. 1 shows a top plan view of one embodiment of a processing system 100 of deposition, etching, baking, and curing chambers according to embodiments. The processing tool 100 depicted in FIG. 1 may contain a plurality of process chambers, 114A-D, a transfer chamber 110, a service chamber 116, an integrated metrology chamber 117, and a pair of load lock chambers 106A-B. The process chambers may include structures or components similar to those described in relation to FIG. 2, as well as additional processing chambers.

To transport substrates among the chambers, the transfer chamber 110 may contain a robotic transport mechanism 113. The transport mechanism 113 may have a pair of substrate transport blades 113A attached to the distal ends of extendible arms 113B, respectively. The blades 113A may be used for carrying individual substrates to and from the process chambers. In operation, one of the substrate transport blades such as blade 113A of the transport mechanism 113 may retrieve a substrate W from one of the load lock chambers such as chambers 106A-B and carry substrate W to a first stage of processing, for example, an etching process as described below in chambers 114A-D. If the chamber is occupied, the robot may wait until the processing is complete and then remove the processed substrate from the chamber with one blade 113A and may insert a new substrate with a second blade (not shown). Once the substrate is processed, it may then be moved to a second stage of processing. For each move, the transport mechanism 113 generally may have one blade carrying a substrate and one blade empty to execute a substrate exchange. The transport mechanism 113 may wait at each chamber until an exchange can be accomplished.

Once processing is complete within the process chambers, the transport mechanism 113 may move the substrate W from the last process chamber and transport the substrate W to a cassette within the load lock chambers 106A-B. From the load lock chambers 106A-B, the substrate may move into a factory interface 104. The factory interface 104 generally may operate to transfer substrates between pod loaders 105A-D in an atmospheric pressure clean environment and the load lock chambers 106A-B. The clean environment in factory interface 104 may be generally provided through air filtration processes, such as HEPA filtration, for example. Factory interface 104 may also include a substrate orienter/aligner (not shown) that may be used to properly align the substrates prior to processing. At least one substrate robot, such as robots 108A-B, may be positioned in factory interface 104 to transport substrates between various positions/locations within factory interface 104 and to other locations in communication therewith. Robots 108A-B may be configured to travel along a track system within interface 104 from a first end to a second end of the factory interface 104.

The processing system 100 may further include an integrated metrology chamber 117 to provide control signals, which may provide adaptive control over any of the processes being performed in the processing chambers. The integrated metrology chamber 117 may include any of a variety of metrological devices to measure various film properties, such as thickness, roughness, composition, and the metrology devices may further be capable of characterizing grating parameters such as critical dimensions, sidewall angle, and feature height under vacuum in an automated manner.

Turning now to FIG. 2 is shown a cross-sectional view of an exemplary process chamber system 200 according to the present technology. Chamber 200 may be used, for example, in one or more of the processing chamber sections 114 of the system 100 previously discussed Generally, the etch chamber 200 may include a first capacitively-coupled plasma source to implement an ion milling operation and a second capacitively-coupled plasma source to implement an etching operation and to implement an optional deposition operation. The ion milling operation may also be called a modification operation. The chamber 200 may include grounded chamber walls 240 surrounding a chuck 250. In embodiments, the chuck 250 may be an electrostatic chuck that clamps the substrate 202 to a top surface of the chuck 250 during processing, though other clamping mechanisms as would be known may also be utilized. The chuck 250 may include an embedded heat exchanger coil 217. In the exemplary embodiment, the heat exchanger coil 217 includes one or more heat transfer fluid channels through which heat transfer fluid, such as an ethylene glycol/water mix, may be passed to control the temperature of the chuck 250 and ultimately the temperature of the substrate 202.

The chuck 250 may include a mesh 249 coupled to a high voltage DC supply 248 so that the mesh 249 may carry a DC bias potential to implement the electrostatic clamping of the substrate 202. The chuck 250 may be coupled with a first RF power source and in one such embodiment, the mesh 249 may be coupled with the first RF power source so that both the DC voltage offset and the RF voltage potentials are coupled across a thin dielectric layer on the top surface of the chuck 250. In the illustrative embodiment, the first RF power source may include a first and second RF generator 252, 253. The RF generators 252, 253 may operate at any industrially utilized frequency, however in the exemplary embodiment the RF generator 252 may operate at 60 MHz to provide advantageous directionality. Where a second RF generator 253 is also provided, the exemplary frequency may be 2 MHz.

With the chuck 250 to be RF powered, an RF return path may be provided by a first showerhead 225. The first showerhead 225 may be disposed above the chuck to distribute a first feed gas into a first chamber region 284 defined by the first showerhead 225 and the chamber wall 240. As such, the chuck 250 and the first showerhead 225 form a first RF coupled electrode pair to capacitively energize a first plasma 270 of a first feed gas within a first chamber region 284. A DC plasma bias, or RF bias, resulting from capacitive coupling of the RF powered chuck may generate an ion flux from the first plasma 270 to the substrate 202, e.g., Ar ions where the first feed gas is Ar, to provide an ion milling plasma. The first showerhead 225 may be grounded or alternately coupled with an RF source 228 having one or more generators operable at a frequency other than that of the chuck 250, e.g., 13.56 MHz or 60 MHz. In the illustrated embodiment the first showerhead 225 may be selectably coupled to ground or the RF source 228 through the relay 227 which may be automatically controlled during the etch process, for example by a controller (not shown). In disclosed embodiments, chamber 200 may not include showerhead 225 or dielectric spacer 220, and may instead include only baffle 215 and showerhead 210 described further below.

As further illustrated in the figure, the etch chamber 200 may include a pump stack capable of high throughput at low process pressures. In embodiments, at least one turbo molecular pump 265, 266 may be coupled with the first chamber region 284 through one or more gate valves 260 and disposed below the chuck 250, opposite the first showerhead 225. The turbo molecular pumps 265, 266 may be any commercially available pumps having suitable throughput and more particularly may be sized appropriately to maintain process pressures below or about 10 mTorr or below or about 5 mTorr at the desired flow rate of the first feed gas, e.g., 50 to 500 sccm of Ar where argon is the first feedgas. In the embodiment illustrated, the chuck 250 may form part of a pedestal which is centered between the two turbo pumps 265 and 266, however in alternate configurations chuck 250 may be on a pedestal cantilevered from the chamber wall 240 with a single turbo molecular pump having a center aligned with a center of the chuck 250.

Disposed above the first showerhead 225 may be a second showerhead 210. In one embodiment, during processing, the first feed gas source, for example, Argon delivered from gas distribution system 290 may be coupled with a gas inlet 276, and the first feed gas flowed through a plurality of apertures 280 extending through second showerhead 210, into the second chamber region 281, and through a plurality of apertures 282 extending through the first showerhead 225 into the first chamber region 284. An additional flow distributor or baffle 215 having apertures 278 may further distribute a first feed gas flow 216 across the diameter of the etch chamber 200 through a distribution region 218. In an alternate embodiment, the first feed gas may be flowed directly into the first chamber region 284 via apertures 283 which are isolated from the second chamber region 281 as denoted by dashed line 223.

Chamber 200 may additionally be reconfigured from the state illustrated to perform an etching operation. A secondary electrode 205 may be disposed above the first showerhead 225 with a second chamber region 281 there between. The secondary electrode 205 may further form a lid or top plate of the etch chamber 200. The secondary electrode 205 and the first showerhead 225 may be electrically isolated by a dielectric ring 220 and form a second RF coupled electrode pair to capacitively discharge a second plasma 292 of a second feed gas within the second chamber region 281. Advantageously, the second plasma 292 may not provide a significant RF bias potential on the chuck 250. At least one electrode of the second RF coupled electrode pair may be coupled with an RF source for energizing an etching plasma. The secondary electrode 205 may be electrically coupled with the second showerhead 210. In an exemplary embodiment, the first showerhead 225 may be coupled with a ground plane or floating and may be coupled to ground through a relay 227 allowing the first showerhead 225 to also be powered by the RF power source 228 during the ion milling mode of operation. Where the first showerhead 225 is grounded, an RF power source 208, having one or more RF generators operating at 13.56 MHz or 60 MHz, for example, may be coupled with the secondary electrode 205 through a relay 207 which may allow the secondary electrode 205 to also be grounded during other operational modes, such as during an ion milling operation, although the secondary electrode 205 may also be left floating if the first showerhead 225 is powered.

A second feed gas source, such as nitrogen trifluoride, C₂F₆, CF₄, or SF₆, and a hydrogen source, such as ammonia, C₂H₂, or H₂, may be delivered from gas distribution system 290, and coupled with the gas inlet 276 such as via dashed line 224. In this mode, the second feed gas may flow through the second showerhead 210 and may be energized in the second chamber region 281. Reactive species may then pass into the first chamber region 284 to react with the substrate 202. As further illustrated, for embodiments where the first showerhead 225 is a multi-channel showerhead, one or more feed gases may be provided to react with the reactive species generated by the second plasma 292. In one such embodiment, a water source may be coupled with the plurality of apertures 283. Additional configurations may also be based on the general illustration provided, but with various components reconfigured. For example, flow distributor or baffle 215 may be a plate similar to the second showerhead 210, and may be positioned between the secondary electrode 205 and the second showerhead 210. As any of these plates may operate as an electrode in various configurations for producing plasma, one or more annular or other shaped spacer may be positioned between one or more of these components, similar to dielectric ring 220. Second showerhead 210 may also operate as an ion suppression plate in embodiments, and may be configured to reduce, limit, or suppress the flow of ionic species through the second showerhead 210, while still allowing the flow of neutral and radical species. One or more additional showerheads or distributors may be included in the chamber between first showerhead 225 and chuck 250. Such a showerhead may take the shape or structure of any of the distribution plates or structures previously described. Also, in embodiments a remote plasma unit (not shown) may be coupled with the gas inlet to provide plasma effluents to the chamber for use in various processes.

In an embodiment, the chuck 250 may be movable along the distance H2 in a direction normal to the first showerhead 225. The chuck 250 may be on an actuated mechanism surrounded by a bellows 255, or the like, to allow the chuck 250 to move closer to or farther from the first showerhead 225 as a means of controlling heat transfer between the chuck 250 and the first showerhead 225, which may be at an elevated temperature of 80° C.-150° C., or more. As such, an etch process may be implemented by moving the chuck 250 between first and second predetermined positions relative to the first showerhead 225. Alternatively, the chuck 250 may include a lifter 251 to elevate the substrate 202 off a top surface of the chuck 250 by distance H1 to control heating by the first showerhead 225 during the etch process. In other embodiments, where the etch process is performed at a fixed temperature such as about 90-110° C. for example, chuck displacement mechanisms may be avoided. A system controller (not shown) may alternately energize the first and second plasmas 270 and 292 during the etching process by alternately powering the first and second RF coupled electrode pairs automatically.

The chamber 200 may also be reconfigured to perform a deposition operation. A plasma 292 may be generated in the second chamber region 281 by an RF discharge which may be implemented in any of the manners described for the second plasma 292. Where the first showerhead 225 is powered to generate the plasma 292 during a deposition, the first showerhead 225 may be isolated from a grounded chamber wall 240 by a dielectric spacer 230 so as to be electrically floating relative to the chamber wall. In the exemplary embodiment, an oxidizer feed gas source, such as molecular oxygen, may be delivered from gas distribution system 290, and coupled with the gas inlet 276. In embodiments where the first showerhead 225 is a multi-channel showerhead, any silicon-containing precursor, such as OMCTS for example, may be delivered from gas distribution system 290, and directed into the first chamber region 284 to react with reactive species passing through the first showerhead 225 from the plasma 292. Alternatively the silicon-containing precursor may also be flowed through the gas inlet 276 along with the oxidizer. Chamber 200 is included as a general chamber configuration that may be utilized for various operations discussed in reference to the present technology. The chamber is not to be considered limiting to the technology, but instead to aid in understanding of the processes described. Several other chambers known in the art or being developed may be utilized with the present technology including any chamber produced by Applied Materials Inc. of Santa Clara, Calif., or any chamber that may perform the techniques described in more detail below.

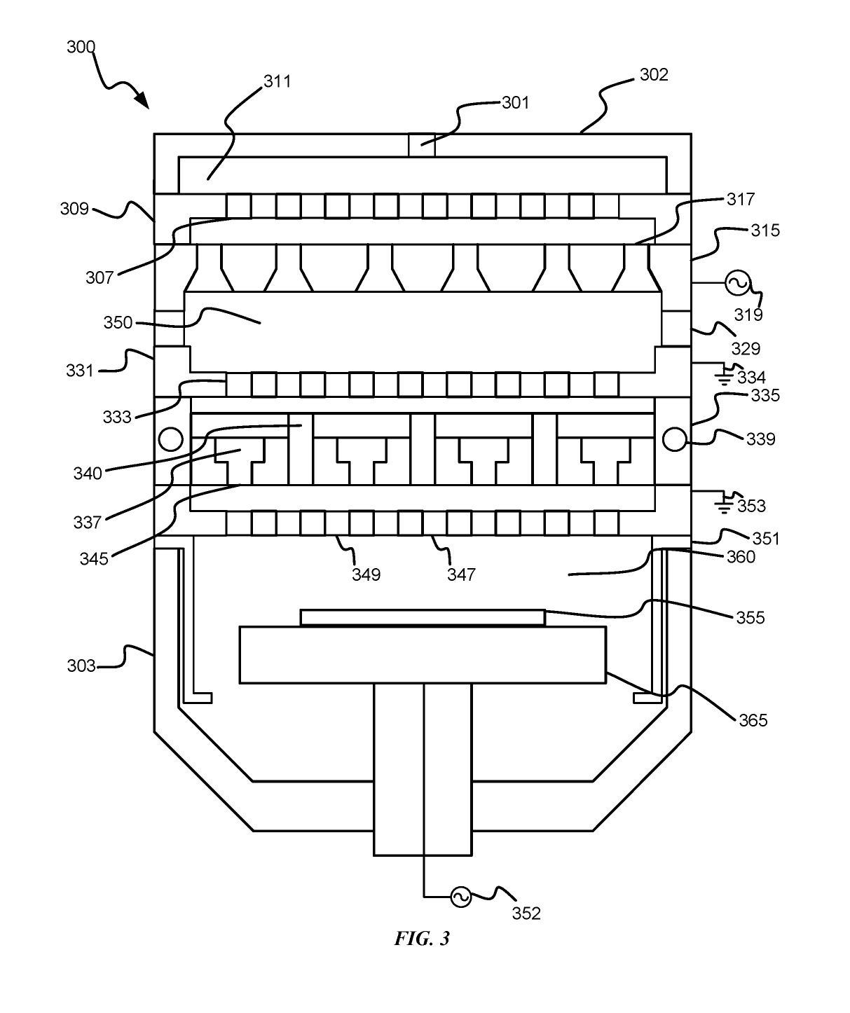

Turning to FIG. 3 is shown a partial schematic view of a processing chamber 300 according to embodiments of the present technology. FIG. 3 may include one or more components discussed above with regard to FIG. 2, and may illustrate further details relating to that chamber, as well as additional embodiments of chambers that may include one or more similar components to those illustrated. The chamber 300 may be used to perform semiconductor processing operations including modification and etching as previously described.

The chamber 300 may be configured to house a semiconductor substrate 355 in a processing region 360 of the chamber. The chamber housing 303 may at least partially define an interior region of the chamber. For example, the chamber housing 303 may include lid 302, and may at least partially include any of the other plates or components illustrated in the figure. For example, the chamber components may be included as a series of stacked components with each component at least partially defining a portion of chamber housing 303. The substrate 355 may be located on a pedestal 365 as shown. Processing chamber 300 may include a remote plasma unit (not shown) coupled with inlet 301. In other embodiments, the system may not include a remote plasma unit, and may be configured to receive precursors directly through inlet 301, which may include an inlet assembly for one or more precursors to be distributed to the chamber 300.

With or without a remote plasma unit, the system may be configured to receive precursors or other fluids through inlet 301, which may provide access to a mixing region 311 of the processing chamber. The mixing region 311 may be separate from and fluidly coupled with the processing region 360 of the chamber. The mixing region 311 may be at least partially defined by a top of the chamber 300, such as chamber lid 302 or lid assembly, which may include an inlet assembly for one or more precursors, and a distribution device, such as showerhead or faceplate 309 below. Faceplate 309 may include a plurality of channels or apertures 307 that may be positioned and/or shaped to affect the distribution and/or residence time of the precursors in the mixing region 311 before proceeding through the chamber.

The chamber 300 may include one or more of a series of components that may optionally be included in disclosed embodiments. For example although faceplate 309 is described, in some embodiments the chamber may not include such a faceplate. Additionally, in disclosed embodiments, the precursors that are at least partially mixed in mixing region 311 may be directed through the chamber via one or more of the operating pressure of the system, the arrangement of the chamber components, or the flow profile of the precursors.

Chamber 300 may additionally include a first showerhead 315. Showerhead 315 may be positioned within the semiconductor processing chamber as illustrated, and may be included or positioned between the lid 302 and the processing region 360. In embodiments, showerhead 315 may be or include a metallic or conductive component that may be a coated, seasoned, or otherwise treated material. Exemplary materials may include metals, including aluminum, stainless steel, or nickel, as well as metal oxides, including aluminum oxide, or any of the materials discussed below. Depending on the precursors being utilized, or the process being performed within the chamber, the showerhead may be any other metal that may provide structural stability as well as conductivity as may be utilized.

Showerhead 315 may define one or more apertures 317 to facilitate uniform distribution of precursors through the showerhead. The apertures 317 may be included in a variety of configurations or patterns, and may be characterized by any number of geometries that may provide precursor distribution as may be desired. Showerhead 315, may be electrically coupled with a power source in embodiments. For example, showerhead 315 may be coupled with an RF source 319 as illustrated. When operated, RF source 319 may provide a current to showerhead 315 allowing a capacitively-coupled plasma (“CCP”) to be formed between the showerhead 315 and a second showerhead 331.

Showerhead 331 may be a second showerhead included within the chamber, and may operate as an additional electrode with showerhead 315. Showerhead 331 may include any of the features or characteristics of showerhead 315 discussed previously. In other embodiments certain features of showerhead 331 may diverge from showerhead 315, such as by defining an aperture profile configured to filter ions from plasma effluents produced in the chamber. For example, showerhead 331 may be coupled with an electrical ground 334, which may allow a plasma to be generated between showerhead 315 and showerhead 331 in embodiments, such as in region 350 defined between the two components. Showerhead 331 may define apertures 333 within the structure to allow precursors or plasma effluents to be delivered to processing region 360.

Chamber 300 optionally may further include a gas distribution assembly 335 within the chamber. In some embodiments, there may be no components between showerhead 331 and processing region 360, and showerhead 331 may allow distribution of precursors or plasma effluents to the processing region 360. The gas distribution assembly 335, which may be similar in aspects to the dual-channel showerheads as previously described, may be located within the chamber above the processing region 360, such as between the processing region 360 and the lid 302, as well as between the processing region 360 and the showerhead 331. The gas distribution assembly 335 may be configured to deliver both a first and a second precursor into the processing region 360 of the chamber. In embodiments, the gas distribution assembly 335 may at least partially divide the interior region of the chamber into a remote region and a processing region in which substrate 355 is positioned.

Although the exemplary system of FIG. 3 includes a dual-channel showerhead, it is understood that alternative distribution assemblies may be utilized that maintain a precursor fluidly isolated from species introduced through inlet 301. For example, a perforated plate and tubes underneath the plate may be utilized, although other configurations may operate with reduced efficiency or not provide as uniform processing as the dual-channel showerhead as described. By utilizing one of the disclosed designs, a precursor may be introduced into the processing region 360 that is not previously excited by a plasma prior to entering the processing region 360, or may be introduced to avoid contacting an additional precursor with which it may react. Although not shown, an additional spacer may be positioned between the showerhead 331 and the gas distribution assembly 335, such as an annular spacer, to isolate the plates from one another. In embodiments in which an additional precursor may not be included, the gas distribution assembly 335 may have a design similar to any of the previously described components, such as any of plates 309, 315, and 331.

In embodiments, gas distribution assembly 335 may include an embedded heater 339, which may include a resistive heater or a temperature controlled fluid, for example. The gas distribution assembly 335 may include an upper plate and a lower plate. The plates may be coupled with one another to define a volume 337 between the plates. The coupling of the plates may be such as to provide first fluid channels 340 through the upper and lower plates, and second fluid channels 345 through the lower plate. The formed channels may be configured to provide fluid access from the volume 337 through the lower plate, and the first fluid channels 340 may be fluidly isolated from the volume 337 between the plates and the second fluid channels 345. The volume 337 may be fluidly accessible through a side of the gas distribution assembly 335, such as channel 223 as previously discussed. The channel may be coupled with an access in the chamber separate from the inlet 301 of the chamber 300.

An additional optional component that may or may not be included in the chamber 300 is faceplate 347, which may also be a dielectric, such as quartz, as well as aluminum or another conductive material, including any of the materials discussed above for showerheads 315, 331. Faceplate 347 may provide similar functionality, and include similar characteristics, as showerheads 315, 331, and may be used in an ion milling or ion etching operation as explained above. For example, when a conductive material, faceplate 347 may be coupled to an electrode, such as coupled with a ground source 353, which in combination with RF source 352 may be used to produce a bias plasma for performing modification operations. In other embodiments the electrical couplings may be reversed. Faceplate 347 may include apertures 349 defined through the structure of the faceplate. Any of the faceplates may have aperture characteristics, patterns, or sizing as discussed throughout this application. The chamber 300 may also include a chamber liner 351, which may protect the walls of the chamber from plasma effluents as well as material deposition, for example. The liner may be or may include a conductive material, and in embodiments may be or include an insulative material. In some embodiments, the chamber walls or liner may operate as an additional electrical grounding source.

A spacer 329 may be positioned between the first showerhead 315 and the second showerhead 331. The spacer may be a dielectric, and may be quartz or any other dielectric material providing insulation between the two components. In embodiments, spacer 329 may be an annular spacer positioned between the two faceplates and contacting both showerheads. In some embodiments, the plasma processing region 350 may be defined in part between the first showerhead 315 and the second showerhead 331. These components may be at least partially configured to at least partially contain a plasma generated between the first showerhead 315 and the second showerhead 331. In some embodiments, these components may be spaced, positioned, or configured to substantially contain the plasma between the two components.

As explained previously, chambers according to some embodiments of the present technology may be used to perform both modification operations in which a bias plasma may be formed in region 360. This operation may be a physical bombardment of structures on a substrate, and may utilize inert or less reactive precursors. Additionally, a reactive etch may be performed by producing reactive plasma effluents in region 350. The precursors may include halogen precursors, which may be configured to remove modified material from a substrate. Accordingly, components of the chamber may be exposed to both chemically reactive plasma effluents, such as fluorine, chlorine, or other halogen-containing effluents, as well as ions produced in the bias plasma used for physical modification. For example, faceplate 347, which may be an additional showerhead, may be exposed to both plasma effluents, such as bias plasma effluents contacting the surface facing the substrate and within apertures, as well as reactive effluents proceeding through apertures 349 before interacting with substrate 355. Other components described above may also be exposed to one or both plasma effluents, including from backstreaming plasma effluents.

The plasma effluents may produce differing effects on the chamber components. For example, ions may be at least partially filtered by showerhead 331 from the chemically reactive plasma effluents produced in region 350. However, the reactive effluents, such as fluorine-containing effluents, for example, may cause corrosion of exposed materials, such as by forming aluminum fluoride. Over time, this process may corrode exposed metallic components, requiring replacement. Additionally, plasma species formed from a bias plasma in region 360 may impact components causing physical damage and sputtering that may erode components over time. Accordingly, any of the described components may be susceptible to chemical corrosion as well as physical erosion from plasma effluents produced within one or more regions of the chamber.

Corrosion may be controlled in some ways by forming a coating over materials. For example, while aluminum may corrode from exposure to fluorine-containing plasma effluents, aluminum oxide, or other platings or coatings, may not corrode on contact with plasma effluents. Accordingly, any of the described components may be coated or protected by anodization, oxidation, electroless nickel plating, electroplated nickel, barium titanate, or any other material that may protect exposed conductive materials, such as aluminum, from chemical corrosion. Similarly, erosion may be controlled in some ways by forming a coating over materials. For example, high performance materials such as e-beam or plasma spray yttrium oxide, which may or may not include additional materials including aluminum or zirconium, for example, may protect the component from physical damage caused by bias plasma effluents. Damage to components may still occur, however, when a structure may be contacted by both corrosive plasma effluents as well as erosive plasma effluents.

Many corrosion resistant coatings may not extend beyond a micron or so in depth, if that much, and thus physical contact by bias plasma effluents may damage and strip the coating over time, which may reveal underlying conductive material, such as aluminum, which may then corrode from additional contact by plasma effluents from the etching process. For example, materials including electroless nickel plating, electroplated nickel, and barium titanate may be readily removed when contacted by erosive plasma effluents such as modifying plasma effluents. Additionally, the processes for forming erosion resistant coatings may be incapable of penetrating high aspect ratio features, and thus may not be capable of fully protecting components from erosion. The present technology, however, may form hybrid or combination coatings, which may provide sufficient protection to extend component life against both corrosion and erosion.

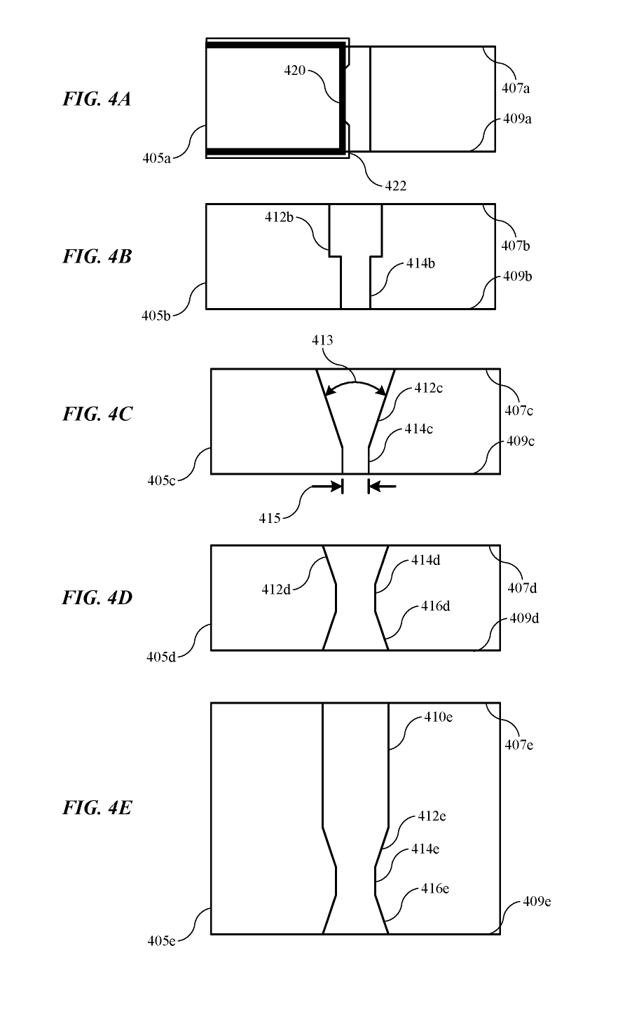

FIGS. 4A-4E illustrate schematic cross-sectional views of exemplary apertures that may be formed in any of the semiconductor chamber components previously discussed according to embodiments of the present technology. The figures provide exemplary views of aperture configurations intended to illustrate possible aperture designs encompassed by embodiments of the present technology. It is to be understood that additional and alternative aperture designs may also be used, and each component may include any number of apertures, such as a plurality of apertures similar to the exemplary aperture of each figure. The apertures are illustrated as extending through an exemplary chamber component 405, which may be an illustration of any of the chamber components previously described, and which may have apertures, including any of the faceplates or showerheads noted above. FIG. 4A illustrates an aperture configuration which may include a straight cylindrical path from a first surface 407a of component 405a to a second surface 409a.

The illustration also includes an exemplary hybrid coating on a left side of the component, which may be formed according to embodiments of the present technology. It is to be understood that the coating may be included on all surfaces of the component in embodiments, and is shown as a partial coverage for illustrative purposes. For example, a first layer 420 of hybrid coating may extend conformally through each aperture of the component 405. As explained previously, the first layer may be a corrosion resistant layer, configured to protect component 405 from reactive etchants, including halogen-containing effluents or etchant materials. The first layer may be or include an anodization, electroless nickel plating, electroplated nickel, aluminum oxide, or barium titanate in embodiments. Due to the formation process for corrosion resistant coatings, complete coverage of the component 405 may be achieved. A depth of coverage may be less than or about 25 μm, and may be less than or about 20 μm, less than or about 15 μm, less than or about 10 μm, less than or about 5 μm, less than or about 3 μm, less than or about 1 μm, less than or about 750 nm, less than or about 500 nm, less than or about 250 nm, less than or about 100 nm, less than or about 50 nm, or less. Because the time to achieve increased thickness may be relatively long in some embodiments, the coating thickness may be between about 100 nm and about 300 nm in some embodiments. In embodiments where the thickness of the first layer may be greater than or about 3 μm or about 5 μm, a second layer may not be included.

A second layer 422 of the hybrid coating may also be included externally to the first layer 420. The second layer may include yttrium oxide, or other high performance materials, such as e-beam coating or yttrium oxide including aluminum, zirconium, or other materials. The second layer 422 may extend at least partially on all surfaces of the component 405, and may extend across a plasma-facing surface of the component. For example, if chamber region 360 may be defined from above by surface 409a, surface 409a may be coated with the second layer, while surface 407a may not be coated in some embodiments as the surface may not be exposed to bias plasma ions, or may have limited exposure. The second layer of hybrid coating may be characterized by a thickness of less than or about 25 μm, and may be characterized by a thickness of less than or about 20 μm, less than or about 15 μm, less than or about 10 μm, less than or about 5 μm, less than or about 1 μm, less than or about 750 nm, less than or about 500 nm, less than or about 300 nm, less than or about 100 nm, or less in some embodiments. The second layer may not fully extend through apertures of the component in some embodiments depending on the coating used. For example, plasma spray may be used to form a yttrium oxide coating, and may be delivered from a plasma spray gun or nozzle. As will be discussed further below, the nozzle may be at an angle for delivery of the coating.

The component 405 may be textured in some embodiments before formation of either or both of the first layer or the second layer of the hybrid coating. For example, coatings may have improved adhesion to textured surfaces. In some embodiments, the texturing may be performed to a depth up to or greater than either or both layer depths of the hybrid coating. For example, prior to coating a first layer, or between the first and second layer coatings, component 405 may be textured via machining, bead or other blasting techniques, or other roughening or texturing operations. The texturing may be performed to a depth of at least about 50 nm, and may be performed to a depth of at least about 100 nm, at least about 250 nm, at least about 500 nm, at least about 750 nm, at least about 1 μm, at least about 3 μm, at least about 5 μm, or more, although the texturing may not extend to a depth greater than the overall thickness of the hybrid coating to limit exposure of underlying materials, and ensure coverage.

Additionally, the apertures may be characterized by a diameter as well as an aspect ratio, which may depend on the profile of the apertures, and which may further affect the second layer of coating. To provide adequate reduction or elimination of plasma effluents, each aperture may be characterized by a diameter at the narrowest cross section of less than or about 0.3 inches, and may be characterized by a diameter of less than or about 0.25 inches, less than or about 0.2 inches, less than or about 0.15 inches, less than or about 0.1 inches, less than or about 0.05 inches, less than or about 0.025 inches or less, although in some embodiments, or for some components, the narrowest cross section may be maintained greater than or about 0.1 inches or more to reduce an associated increase in pressure, which may affect process operations as previously described. The aspect ratio may be defined as an aperture height through the component as a ratio to the diameter at the narrowest cross section of the aperture. In embodiments, the aspect ratio may be greater than, less than, or about 50:1 to reduce a pressure increase across the component. In some embodiments, the aspect ratio may be less than or about 40:1, less than or about 30:1, less than or about 20:1, less than or about 10:1, less than or about 5:1, or less, although the aspect ratio in embodiments may be maintained greater than or about 10:1 to ensure adequate control of plasma species. The combination of relatively-small diameter apertures and high aspect ratios, may further limit the extent of coverage within the aperture of the second layer. The second layer may extend at least partially within the aperture in some embodiments, although in some embodiments the second layer may be maintained on the first surface 407 and/or second surface 409 of the component 405. Although the additional examples of FIG. 4 do not illustrate the hybrid coating, one or both layers of the hybrid coating may be applied to any of the illustrated apertures.

FIG. 4B illustrates an additional aperture profile for a chamber component 405b, in which each aperture of the plurality of apertures may be characterized by a first section 412b extending from first surface 407b to an interior position, and a second section 414b extending from the interior position to second surface 409b. The two sections may both be straight sections, which may be cylindrical, and may define a ledge between the first section and the second section.

FIG. 4C illustrates an additional aperture profile for a chamber component 405c, in which each aperture of the plurality of apertures may be characterized by a first section 412c characterized by a taper extending from a first surface 407c of component 405c at least partially through the aperture. Each aperture may also be characterized by a second section 414c, which may be a straight or cylindrical section, or characterized by substantially straight sidewalls, at least partially extending through each aperture, such as from first section 412c to second surface 409c of component 405c. First section 412c may be characterized by an angle of taper 413, which may be between about 5° and about 120°. The diameter of first section 412c at first surface 407c may depend on the height of the plate and depth of the first section at the determined angle, and in some embodiments, the diameter of each aperture at first surface 407 may be less than or about 10 mm, although thicker plates, such as greater than or about 4 inches, may be characterized by greater diameters at the first surface. Additionally, second section 414c may be characterized by a diameter 415, which may be any of the diameters previously described. Additionally, in some embodiments the second section 414c may be characterized by a height through the component 405. In some embodiments, the diameter may be equal to or greater than the height, and may be up to twice the height dimension or more. These aspects may improve coating of the second layer in some embodiments as will be explained further below.

FIG. 4D illustrates an additional embodiment in which apertures may include a third section through the component 405. As illustrated, component 405d may include apertures having a first section 412d similar to section 412c discussed above and extending from first surface 407e, and a second section 414d similar to section 414c discussed above. The first section 412d and second section 414d may be characterized by similar dimensional characteristics to those described for component 405c. Additionally, apertures of component 405d may include a third section 416d, which may be characterized by a flare. For example, the apertures may include first section 412d extending from first surface 407d to a position intersecting second section 414d. Second section 414d may extend from first section 412d to a position intersecting third section 416d. Third section 416d may extend from second section 414d to second surface 409d of component 405d. Third section 416d may be characterized by an angle of flare, which may be greater than or less than the angle of taper, and may be of any of the angles previously noted. In some embodiments, the angle of flare may be equal to the angle of taper.

FIG. 4E illustrates an additional aperture design, which may limit coverage of second layer 422 of the hybrid coating within the aperture. Component 405e may include apertures including a first straight or cylindrical section 410e, which may extend to a second section 412e, and which may be characterized by an angle of taper. Second section 412e may extend to a third section 414e, which may be characterized by a straight or cylindrical profile. Third section 414e may extend to a fourth section 416e, which may extend to second surface 409e of component 405e. Although fourth section 416e may be coated by a second layer of the hybrid coating, as well as at least a portion of third section 414e, first section 412e may have limited or no coverage from the second layer of the hybrid coating due to the profile of the apertures, which may limit access from a plasma spray. It is to be understood that FIG. 4 illustrates only example aperture configurations, and that a variety of additional and alternative aperture designs are similarly encompassed by the present technology.

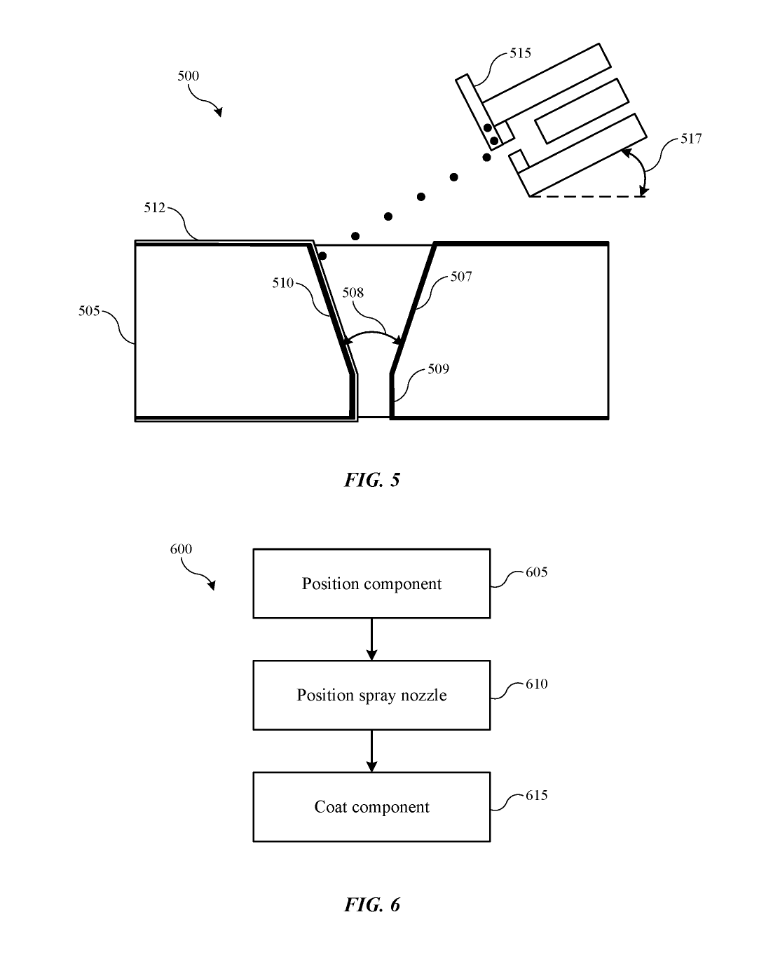

FIG. 5 illustrates a schematic cross-sectional view of a coating system 500 for coating a chamber component according to some embodiments of the present technology. The chamber and component may be used in a variety of processes for coating one or more materials onto semiconductor chamber components. FIG. 6 illustrates exemplary operations in method 600 according to some embodiments of the present technology, and will be discussed in conjunction with the coating system components of FIG. 5.

As illustrated, a component 505 may be positioned within a coating chamber, such as on a stage, in operation 605. The component 505 may be any of the faceplates, showerheads, or components including apertures as previously described. Any of the previously discussed aperture profiles may be incorporated by the component, although the configuration of FIG. 4C will be discussed to explain additional benefits of the present technology. As previously noted, the aperture may be characterized by a first section 507 including a taper, and a second section 509 including a cylindrical or straight profile. First section 507 may be characterized by an angle of taper 508, which in embodiments may be less than 90°. Additionally, second section 509 may be characterized by a diameter and a height of the second section, and in embodiments the diameter may be equal to or greater than the height of the second section 509. In some embodiments the diameter may be less than or about twice the height. By maintaining dimensions within these ranges, improved coverage of a second layer of a hybrid coating may be afforded.

A first layer 510 of a hybrid coating, which may be a corrosion resistant layer, may be formed previously, and may fully extend through each aperture and on all surfaces of the component 505. The first layer may be formed within the same chamber or tool as the second layer, or may be formed separately and the component may then be positioned within the coating chamber for a second layer of coating. The second layer 512 of coating may be a plasma spray coating, which may be yttrium oxide, and which may include any of the additional elements noted previously. A spray nozzle 515, which may be a plasma spray nozzle or gun, may be positioned in operation 610. The nozzle may be positioned relative to the component 505, and may be positioned so that the nozzle is positioned at nozzle angle 517, which may also be less than 90 degrees. In some embodiments the nozzle angle 517 and the angle of taper may be added together to equal 90 degrees, or put another way, the nozzle angle may be defined as about 90 minus the angle of taper. The component may then be coated with a second layer of the hybrid coating at operation 615. The method may optionally include laterally translating the component during the coating, which may include x-y translation and rotation on a stage, while the spray nozzle is fixed.

By forming apertures with these characteristics, improved aperture coating may be performed. In some embodiments the nozzle angle is greater than the angle of taper. For example, the nozzle angle may be greater than or about 45° in some embodiments, including greater than 60°, and the angle of taper may be less than or about 45°, including less than 30°. Additionally, second section 509, by maintaining a diameter greater than the height, may similarly afford complete coverage through second section 509. Accordingly, in some embodiments, coating the component for the second layer, or with an erosion or environmental resistant coating, may provide greater than 95% coverage within the apertures, such as on all surface areas of the component defining each aperture. In some embodiments the coating may provide greater than or about 97% coverage, greater than or about 99% coverage, greater than or about 99.9% coverage, or substantially or essentially complete coverage on all surfaces within the aperture.

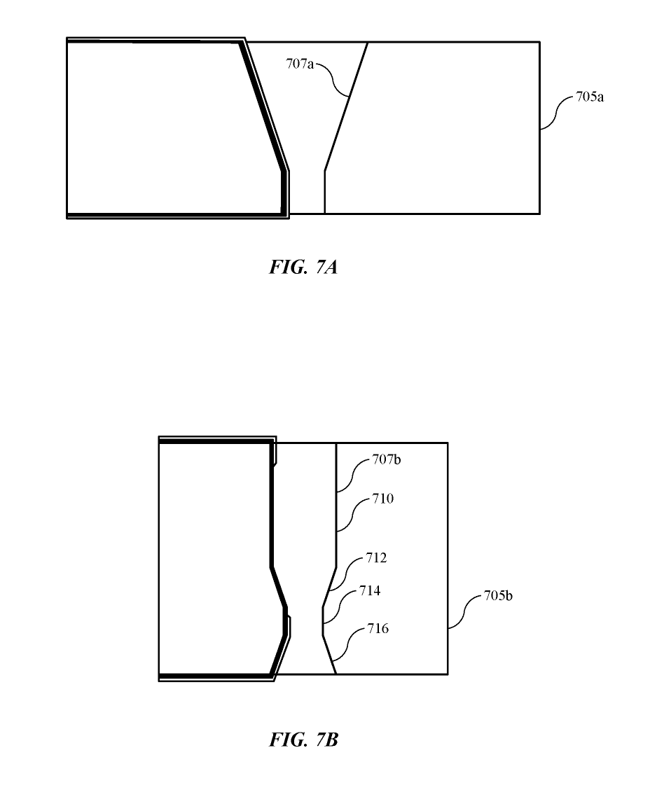

The coverage may depend on the aperture configuration, as illustrated in FIGS. 7A-7B. Although the illustrations only show half of the component as coated for ease of illustration and explanation, it is to be understood that the entire component may be similarly coated. For example, for aperture configurations as illustrated in FIGS. 4C and 4D, complete coverage may be afforded. As illustrated in FIG. 7A, coverage may extend on component 705a fully along all sections of aperture 707a. However, depending on the aperture characteristics, coverage may extend on component 705b only partially along sections of aperture 707b. For example, for higher aspect ratio apertures, as well as reduced dimensions, a second layer of coating, such as an erosion resistant coating, may not fully penetrate the aperture. Fourth section 716 of aperture 707b may be characterized by an angle of flare as described above, and may afford complete coating through the fourth section. Third section 714 may similarly be characterized by a diameter and height relationship as previously described, which may allow partial or complete coverage through third section 714. First section 710 may also receive at least partial coverage depending on the aperture characteristics. Second section 712 may receive limited or no coverage depending on the depth from the first surface, and the diameter of the first section. Accordingly, although some aperture designs may afford complete coverage, additional aperture designs may have reduced coverage for a second layer of a hybrid coating in some embodiments.

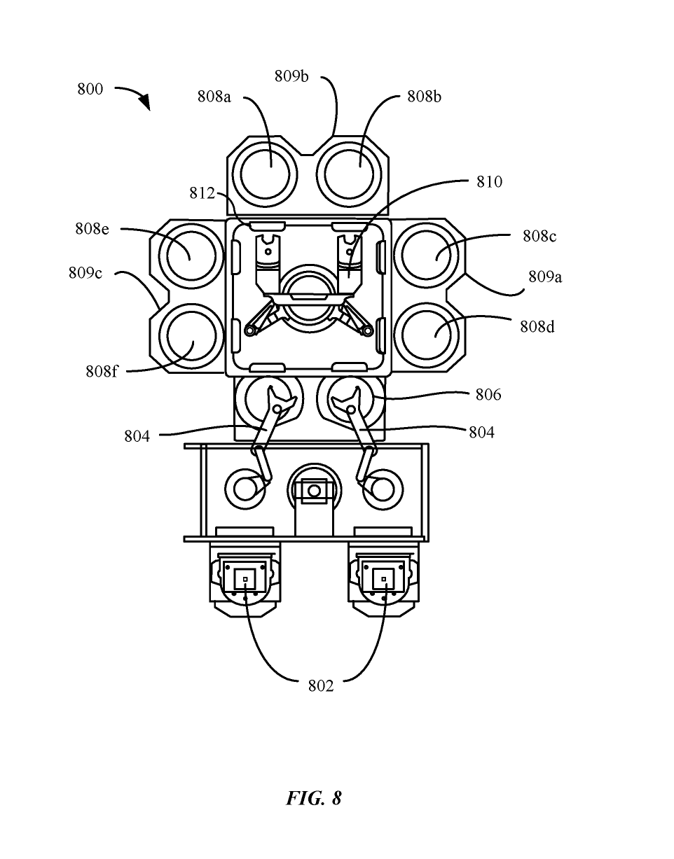

The present technology may be applied to additional chamber components as well, which may limit material formation on the components as well as damage. Turning to FIG. 8 is illustrated a top plan view of an additional exemplary processing system 800 according to some embodiments of the present technology. In the figure, a pair of front opening unified pods (FOUPs) 802 supply substrates of a variety of sizes that are received by robotic arms 804 and placed into a low pressure holding area 806 before being placed into one of the substrate processing chambers 808a-f, positioned in tandem sections 809a-c. A second robotic arm 810 may be used to transport the substrate wafers from the holding area 806 to the substrate processing chambers 808a-f and back. Each substrate processing chamber 808a-f, can be outfitted to perform a number of substrate processing operations including the etch processes described herein in addition to cyclical layer deposition (CLD), atomic layer deposition (ALD), chemical vapor deposition (CVD), physical vapor deposition (PVD), etch, pre-clean, degas, orientation, and other substrate processes. For example, any of the processing chambers 808 may be or include the processing chambers described above.

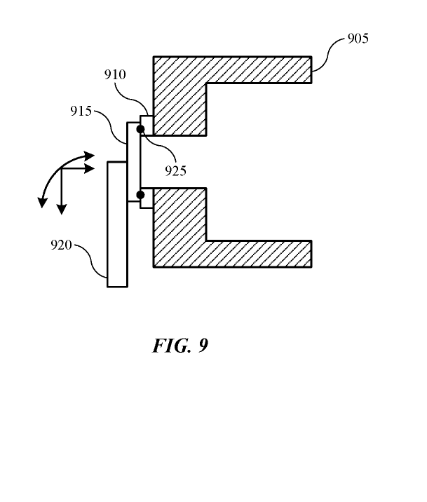

The processing system 800 may additionally include a number slit valves 812 providing access to and from the various sections of the system, including from the processing chambers, as well as to and from holding area 806. These slit valves may provide access between regions at different pressures, including at low pressure and atmospheric pressure, which may introduce an amount of moisture, which may interact with other materials during operations, and deposit materials on interior surfaces of the slit valves, or cause corrosion of the slit valve. FIG. 9 illustrates a schematic cross-sectional view 900 of a processing chamber and slit valve according to some embodiments of the present technology. Chamber 905 may include an access through which substrates may be delivered and retrieved from a processing region. The access may directly connect with a processing region, such as processing region 360 previously described. An interface connector 910 may be coupled with the chamber 905. Slit valve 915 may be in removable contact with interface connector 910, and may be connected with a motorized arm 920, which may open and close slit valve 915. Slit valve 915 may be modulated to and from the chamber in a number of motions including S or L-shaped motions as indicated by the directional lines. In other embodiments slit valve 915 may be raised or lowered directly.

During movement, either from scraping or impact, materials formed on or produced by the slit valve may sluff off the chamber-facing surface of the slit valve, and into the chamber. These materials may then be present during operation, and may cause unwanted deposition on a substrate. Accordingly, in some embodiments, slit valve 915 may include the hybrid coating on one or more surfaces of the slit valve, including on the chamber-facing surface of the slit valve. On the same surface of the slit valve 915 may be an o-ring 925 or additional element allowing a vacuum seal to be produced at the interface connector 910. O-ring 925 may be positioned externally to the coating, and thus an amount of surface texturing may be performed about the location where the o-ring may be applied. Accordingly, texturing may be uneven about the slit valve, and texturing may be formed to a depth greater than the thickness of the hybrid coating along a location of where the o-ring will be coupled to the slit valve to ensure a textured surface to facilitate coupling.

By forming the hybrid coating on additional components such as slit valve 915, reduced particle contamination and defects may occur on substrates being processed. In embodiments of the present technology using hybrid coatings on one or more chamber components discussed, wafer-level particle contribution sizes of 65 nm, 35 nm, and 20 nm and less may be reduced. For example, in embodiments of the present technology using hybrid coatings on one or more chamber components discussed, wafer-level particle contribution of 35 nm size from the semiconductor chamber components may be reduced to less than or about 100 adders, and may be reduced to less than or about 50 adders, less than or about 20 adders, less than or about 10 adders, less than or about 5 adders, less than or about 2 adders, less than or about 1 adder or less. Consequently, the present technology may improve device production, while additionally increasing component life within the processing chamber.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a layer” includes a plurality of such layers, and reference to “the precursor” includes reference to one or more precursors and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor chamber component comprising:
an aluminum, stainless steel, or nickel plate defining a plurality of apertures, wherein:
the plate includes a hybrid coating, the hybrid coating comprising:
a first layer comprising a corrosion resistant coating, wherein the first layer extends conformally through each aperture of the plurality of apertures, and
a second layer comprising an erosion resistant coating extending across a plasma-facing surface of the semiconductor chamber component.

2. The semiconductor chamber component of claim 1, wherein the first layer comprises an anodization, electroless nickel plating, electroplated nickel, aluminum oxide, or barium titanate.

3. The semiconductor chamber component of claim 2, wherein the first layer is characterized by a thickness of less than or about 25 μm.

4. The semiconductor chamber component of claim 1, wherein the second layer comprises yttrium oxide.

5. The semiconductor chamber component of claim 4, wherein the second layer is characterized by a thickness of less than or about 25 μm.

6. The semiconductor chamber component of claim 4, wherein the second layer further includes aluminum or zirconium within the yttrium oxide.

7. The semiconductor chamber component of claim 1, wherein surfaces of the plate are textured to a depth of at least about 1 μm.

8. The semiconductor chamber component of claim 1, wherein the plurality of apertures are characterized by a taper at least partially extending through each aperture and a straight section at least partially extending through each aperture.

9. The semiconductor chamber component of claim 8, wherein a diameter of the straight section is less than or about twice a height of the straight section.

10. The semiconductor chamber component of claim 8, wherein each aperture of the plurality of apertures extends from a first surface of the plate to a second surface of the plate opposite the first surface, and wherein a diameter of each aperture at the first surface is less than or about 10 mm.

11. The semiconductor chamber component of claim 1, wherein the hybrid coating is configured to reduce wafer-level particle contribution from the semiconductor chamber component to less than or about 5 adders of size 35 nm.

12. A method of coating a component of a semiconductor processing chamber, the method comprising:
positioning the component within a chamber, wherein the component defines a plurality of apertures including a taper extending at least partially through a first section of each aperture of the plurality of apertures, and wherein the taper is characterized by an angle of taper through the first section of each aperture of the plurality of apertures;
positioning a spray nozzle at a nozzle angle relative to the component, wherein the nozzle angle is defined as about 90 minus the angle of taper; and
coating the component.

13. The method of coating a component of a semiconductor processing chamber of claim 12, wherein the coating comprises a plasma-sprayed coating of yttrium oxide.

14. The method of coating a component of a semiconductor processing chamber of claim 13, wherein the coating further comprises particles of aluminum or zirconium within the yttrium oxide.

15. The method of coating a component of a semiconductor processing chamber of claim 12, further comprising laterally translating the component during the coating while the spray nozzle remains fixed.

16. The method of coating a component of a semiconductor processing chamber of claim 12, wherein each aperture of the plurality of apertures further comprises a second section characterized by a cylindrical profile, and wherein the second section is characterized by a diameter less than or equal to twice a height of the second section.

17. The method of coating a component of a semiconductor processing chamber of claim 16, wherein the component is characterized by a first surface and a second surface opposite the first surface, wherein the first section of each aperture extends from the first surface to the second section of each aperture, wherein the second section of each aperture extends from the first section of each aperture to a third section of each aperture, wherein the third section of each aperture flares from the second section of each aperture to the second surface of the component, and wherein an angle of flare is equal to the angle of taper.

18. The method of coating a component of a semiconductor processing chamber of claim 12, wherein coating the component coats greater than 95% of a surface area of the component defining each aperture.

19. A semiconductor processing chamber comprising:
a processing region configured to house a substrate, wherein a bias plasma is formable within the processing region;
a remote plasma region within which a remote plasma is formable; and
a plate positioned between the processing region and the remote plasma region, wherein the plate at least partially defines the processing region, wherein the plate comprises a first surface facing towards the remote plasma region and a second surface facing towards the processing region, wherein the second surface is opposite the first surface, wherein the plate defines a plurality of apertures, and wherein the plate includes a hybrid coating comprising:
a first layer comprising a corrosion resistant coating, wherein the first layer extends conformally through each aperture of the plurality of apertures, and
a second layer comprising an erosion resistant coating extending across the second surface of the plate facing the processing region of the semiconductor processing chamber.

20. The semiconductor processing chamber of claim 19, further comprising a slit valve configured to provide access to the processing region, wherein a chamber-facing surface of the slit valve includes the hybrid coating extending across the slit valve and between the slit valve and a seal coupled with the slit valve.
